(19) United States
(12) Patent Application Publication
(10) Pub. No.: US 2026/0038587 A1
(43) Pub. Date: Feb. 5, 2026

(54) CLOCKING SCHEME FOR MULTI-PORT REGISTER FILE

(71) Applicant: Arm Limited, Cambridge (GB)

(72) Inventors: Rahul MATHUR, Austin, TX (US); Andy Wangkun CHEN, Austin, TX (US)

(21) Appl. No.: 18/791,057

(22) Filed: Jul. 31, 2024

(51) Int. Cl. G11C 11/419; G11C 11/412; G11C 11/418; H03K 19/20

(52) U.S. Cl. CPC G11C 11/419; G11C 11/418; G11C 11/412; H03K 19/20

(57) ABSTRACT

A clocking scheme for a driving a first signal and a write word line signal to a multi-port memory device, the clocking scheme comprising:
a clock configured to control timing of operations within the multi-port memory device, wherein the clocking scheme includes at least two separate clocking phases; and
activating the first signal line and the write word line in different clock phases of the clocking scheme, such that the first signal line is activated in a first clock phase and the write word line is activated in a second clock phase.

### FIELD

The present technology relates to a clocking scheme for a multi-port register file and to circuits configured to generate signals for the clocking scheme.

### BACKGROUND

In conventional semiconductor fabrication designs, multi-port memory designs suffer from routing congestion issues such as crosstalk. Also, bitcell area is increasing on modern designs that typically degrade performance and increase power, which often causes additional inefficiencies in common bitcell designs.

Prior art memory limitations in bitcell designs can manifest as bit line to word line coupling where a bit line driven low from a write driver can actively couple to a word line signal negatively impacting writability. Some bitcell designs have collision issues where a simultaneous read and write to the same address is not supported in the same clock cycle. A read address AA and write address BB may be identical and a memory output can become an “x” as a bitcell content is unknown.

Therefore, to overcome the deficiencies of conventional bitcell designs, improved multi-port memory circuits having more efficient multi-port bitcell designs are needed to improve crosstalk and collision issues.

### SUMMARY

According to a first aspect of present techniques, there is provided a clocking scheme for a driving a first signal and a write word line signal to a multi-port memory device, the clocking scheme comprising: a clock configured to control timing of operations within the multi-port memory device, wherein the clocking scheme includes at least two separate clocking phases; and activating the first signal line and the write word line in different clock phases of the clocking scheme, such that the first signal line is activated in a first clock phase and the write word line is activated in a second clock phase.

The clocking scheme may comprise a clock signal having a rising edge in the first clock phase and a falling edge in the second clock phase. The first signal line may be a write bit line. The write bit line may be triggered to rise at the rising edge of the clock signal and the write word line is triggered to rise at the falling edge of the clock signal and the write word line rise may trigger a writing of data from the write bit line to a storage node of a bit cell.

In techniques, the writing of data is a state of a 0 or 1.

According to the clocking scheme, a falling time of the write word line may be determined by self-timed path delay. The first signal line may be an OR write word line and the OR write word line may be triggered to rise at the rising edge of the clock signal and the write word line is triggered to rise at the falling edge of the clock signal.

The first signal line may be a read word line and may be triggered to rise at the rising edge of the clock signal and the write word line is triggered to rise at the falling edge of the clock signal.

In techniques, the clocking scheme may comprise a clock coupled to a both a read clock and a write clock, wherein for a read operation the read clock rises to trigger a read word line rise followed by the read clock falling to trigger the read word line fall. For a write operation the write clock rises may trigger a write bit line rise or fall and for a write operation the write clock falls may trigger write word line rise at the falling edge of the write clock.

According to a second aspect of present techniques, there is provided a logic circuit for driving signals to a multi-port memory device, the logic circuit comprising: a first signal line; a write word line; a clocking scheme configured to control timing of operations within the multi-port memory device, wherein the clocking scheme includes at least two separate clocking phases; wherein the first signal line and the write word line are activated in different clock phases of the clocking scheme, such that the first signal line is activated in a first clock phase and the write word line is activated in a second clock phase.

The first signal line may be a write word line configured as an OR of the write word lines of all different write ports. The OR of the write word line may be generated by an input array of write ports each coupled to an input of a first NOR gate, wherein at least three first NOR gates are coupled to an input of a second NOR gate coupled to an input of a NAND gate and wherein the NAND gate is coupled to an input of a third NOR gate connected to an input of a NOT gate.

The input of the NAND gate may be coupled to at least three second NOR gates and wherein the third NOR gate is coupled at an input to an output of a first NOR gate and an output of the NAND gate.

According to a third aspect of present techniques, there is provided a non-transitory computer-readable medium to store computer-readable code for fabrication of the circuit described herein.

Present techniques resolve dynamic coupling issues with the memory by separating the activation of the signal lines. There are three different separations which are as follows: in the write stage this is separation of the WBL and WWL; the OR_WWL and WWL and then also the RWL and the WWL. But in all cases the WWL comes second which is a unifying feature of all three aspects of the present techniques.

According to a further aspect of present techniques, there is provided a non-transitory computer-readable medium to store computer-readable code for fabrication of any circuitry described herein.

Accordingly, concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively, or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Implementations of the present technology each have at least one of the above-mentioned objects and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

Implementations of various techniques are described herein with reference to the accompanying drawings. It should be understood, however, that the accompanying drawings illustrate only various implementations described herein and are not meant to limit embodiments of various techniques described hereon. Embodiments will now be described, with reference to the accompanying drawings, in which:

FIG. 1 shows a storage node configured as a multi-transistor bitcell;

FIG. 2 shows a circuit for read word line signal generation;

FIG. 3 shows a circuit for write bit line signal generation;

FIG. 4 shows a circuit for OR write word line signal generation;

FIG. 5 shows a circuit for write word line signal generation;

FIG. 6 shows a series of signal waveforms generated from the circuits of FIGS. 2 to 6; and

FIG. 7 shows a signal flow chart for a read and write operation in a multi-port register circuit.

### DETAILED DESCRIPTION

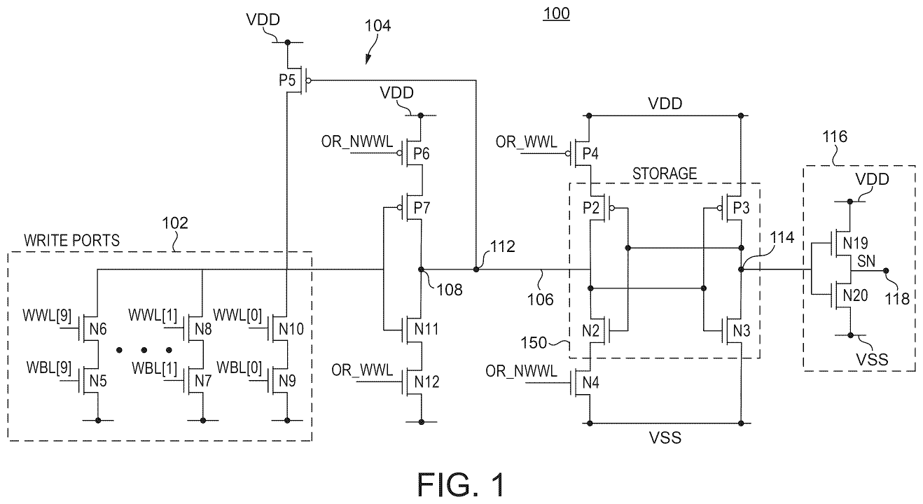

As shown in FIG. 1, a multi-port bitcell macro 100 comprises a storage node 150 configured as a multi-transistor bitcell, such as a four transistor (4T) tri-stated bitcell. Also, the storage node 150 is implemented as a static random access memory (SRAM) structure that is configured to store at least one data-bit value such as a data value related to a logical “0” or “1”. The storage node 150 has multiple transistors (P2/N2, P3/N3) that are coupled together as cross-coupled inverters, wherein a first inverter (P2/N2) has transistor (P2) coupled in series with transistor (P4) and a source voltage (VDD). Transistor (N2) is coupled in series with transistor (N4) and ground (VSS or Gnd). A second inverter (P3/N3) has transistor (P3) coupled in series with transistor N3 between source voltage (VDD) and ground (VSS or Gnd).

The multi-port bitcell macro 100 comprises an input stage 102 comprising write ports including an array of transistors arranged in columns. First column comprises a transistor (N5) coupled in series with transistor (N6) wherein the drain terminal of transistor (N5) is coupled to ground (VSS or Gnd) and the source terminal of transistor N6 is coupled to a control stage 104. Second column comprises a transistor (N7) coupled in series with transistor (N8) wherein the drain terminal of transistor (N7) is coupled to ground (VSS or Gnd) and the source terminal of transistor (N8) is coupled to a control stage 104. Third column comprises a transistor (N9) coupled in series with transistor (N10) wherein the drain terminal of transistor (N9) is coupled to ground (VSS or Gnd) and the source terminal of transistor (N10) is coupled to pre-charge transistor (P5) coupled the between the source voltage (VDD) and the transistor (N10) and a gate terminal of transistor (P5) coupled to a node 112 which is coupled to the storage node 150 by way of a node 110. The pre-charge transistor (P5) is a p-type transistor.

The input stage 102 comprises columns of write wordline (WWL) ports and and write bitline (WBL) ports coupled to the input stage 102. In FIG. 1, three write ports are illustrated out of ten write ports according to present techniques.

The control stage 104 comprises a transistor (P6) coupled in series between source voltage (VDD) and transistor (P7). Transistor (P7) is coupled in series with transistor (N11). A gate terminal of transistor (P7) is coupled to the gate terminal of transistor (N11). Transistor (N11) is coupled in series with transistor (N12). Transistor (N12) is coupled in series between transistor (N11) and ground (VSS or Gnd). The control stage is configured to perform a first write based on an internal bitline signal and a first write worldline signal (OR_NWWL) and a second write worldline signal (OR_WWL). The control stage 104 outputs the internal bitline signal as an output signal when activated by the first write worldline signal (OR_NWWL) and the second write worldline signal (OR_WWL).

The control stage 104 is coupled to the storage node 150 by way of a trace 106 coupled to a node 108 located between the drain terminal of transistor (P7) and source terminal of transistor (N11) and coupled to the node 110 located between the first inverter (P2/N2). Additionally, the gate terminal of transistor (P5) is coupled to the trace 106 at the node 112 located between an output of the control stage 104 and input to the storage node 150. Also, the second write wordline signal (OR_WWL) is coupled to the gate terminal of transistor (P4) for activation by the second write wordline signal (OR_WWL). Further, the first write wordline signal (OR_NWWL) is coupled to the gate terminal of transistor (N4) for activation by the first write wordline signal (OR_NWWL).

The write wordline (WWL) ports and write bitline (WBL) ports provide an internal bitline signal to the control stage 104 when activated by the selected write wordline (WWL) signal from at least one write wordline (WWL) port of the write wordline (WWL) ports and also when activated by the selected write bitline (WBL) signal on at least one write bitline (WBL) port of the write bitline (WBL) ports.

The storage node 150 has output node 114 coupled to an inverter 116 to drive storage node 150 output. The inverter 116 comprises transistor N19 coupled in series to transistor N20. A gate terminal of transistor N19 is coupled to a gate terminal of transistor N20 and both gate terminals are coupled to the output node 114. The transistor N19 is coupled to the source voltage (VDD) and the transistor N20 is coupled to ground (VSS or Gnd). Storage node output 118 is coupled between the drain and source terminal of the transistor N19 and transistor N20 respectively and is coupled to a Read Multiplexer circuit (not shown in FIG. 1).

During a write operation, the write wordline (WWL) is activated, which transfers a flopped data (WBL) onto the storage node 150 and storage node output 118. Storage node outputs from all bitcells from different rows are multiplexed and latched in the Read Multiplexer circuit.

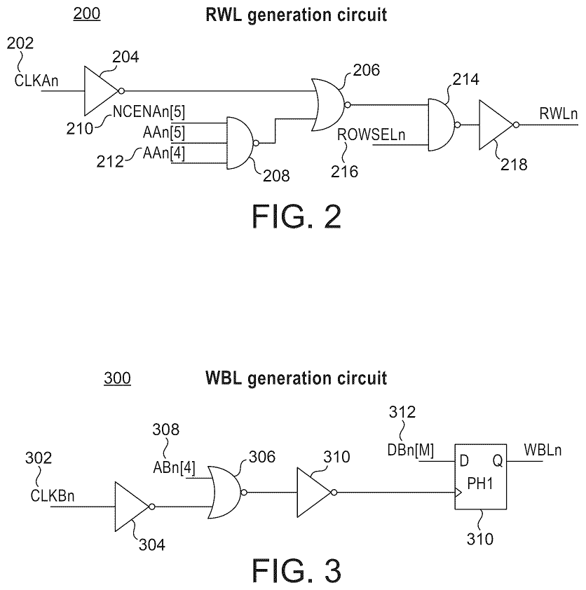

FIG. 2 shows a circuit 200 for read word line signal generation. Clock A 202 representing a read clock is coupled to an input terminal of a first NOT gate 204 comprising an output terminal connected to a first input terminal of a first NOR gate 206. A first NAND gate 208 comprises a chip enable input 210 coupled to a first input terminal of the first NAND gate 208 and further inputs AAn 212 coupled to a second input terminal and third input terminal of the first NAND gate 208. As will be understood by a person skilled in the art, the output of the first NAND gate 208 for the given terminal inputs depends on a combination of values for the chip enable input 210 and the further inputs AAn 210. An output terminal of the first NAND gate 208 is coupled to a second input terminal of the first NOR gate 206. The first NOR gate 206 comprises an output terminal coupled to a first input terminal of a second NAND gate 214. The second NAND gate comprises a second input terminal coupled to a row select signal 216 for selecting a read from a storage node and an output terminal coupled to a first input terminal of a second NOT gate 218. An output terminal of the second NOT gate 218 is configured to output a read word line RWLn rise or fall signal corresponding to the clock A 202 rise or fall signal.

FIG. 3 shows a circuit 300 for write bit line signal generation. Clock B 302 representing a write clock is coupled to an input terminal of a first NOT gate 304 comprising an output terminal coupled to a first input terminal of a first NOR gate 306. The first NOR gate 306 comprises a second input terminal for input ABn 308. The first NOR gate 306 comprises an output terminal connected to an input terminal of a NOT gate 310. The NOT gate 310 comprises an output terminal coupled to a first input terminal of a D latch 312. The D latch 312 comprises Data D representing the input to the D latch 312, a Q representing an output of the D latch reflecting a stored value and a PH1 or clock signal used to control when the value of DBn [M] 312 input to an input terminal of the D latch 312 is sampled and transferred to the Q output. As will be understood by a person skilled in the art, the Q output changes state based on the DBn [M] 312 input and the clock signal, when the clock signal transitions on a rising or falling edge. An output terminal of the D latch 312 is configured to output a write bit line WBLn rise or fall signal corresponding to the clock B 302 rise or fall signal.

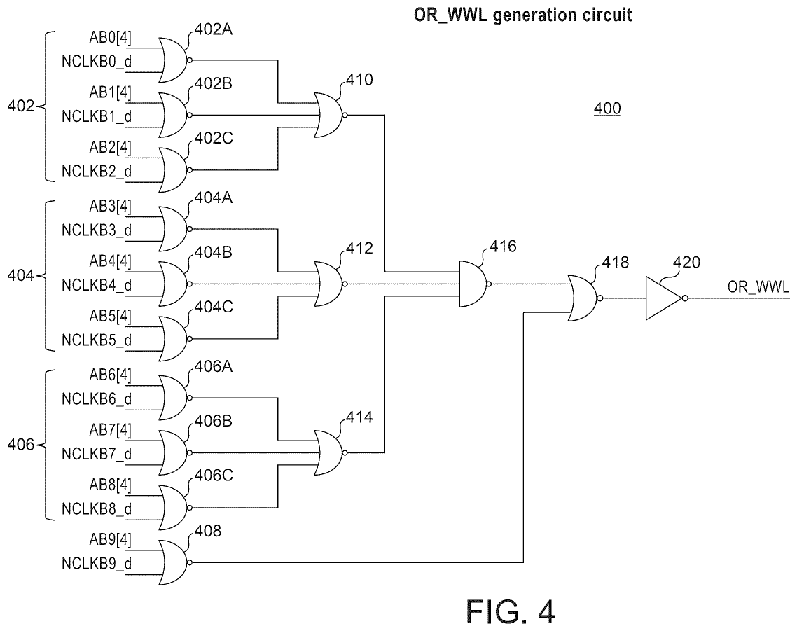

FIG. 4 shows a circuit 400 for OR write word line signal OR_WWL generation. An OR write word line carries an OR version of the write word line WWL.

Referring to FIG. 4, a first array of NOR gates 402 comprises three NOR gates: first 402A, second 402B and third 402C. Also shown in FIG. 4 is a second array of NOR gates 404 comprising three NOR gates: fourth 404A, fifth 404B and sixth 404C and a third array of NOR gates 406 comprising three NOR gates: seventh 406A, eight 406B and ninth 406C. Each NOR gate: first 402A, second 402B and third 402C . . . to ninth NOR gate 406C comprises two input terminals to receive at one terminal a combined AB signal and at the other terminal a NCLK signal, or not clock signal also known as an inverted clock signal. The clock signal is an inverted write clock signal to synchronize operations.

A tenth NOR gate 408 forms part of the circuit 400 but is not part of an array of NOR gates. The tenth NOR gate 408 comprises two input terminals to receive at one terminal a combined AB signal and at the other terminal a NCLK signal, or not clock signal also known as an inverted clock signal. The clock signal is an inverted write clock signal to synchronize operations.

Each NOR gate of the first array of NOR gates 402, the second array of NOR gates 404 and the third array of NOR gates 406 comprise an output terminal coupled to one of three input terminals respectively of a further NOR gate, eleventh NOR gate 410, twelfth NOR gate 412 and thirteenth NOR gate 414. For example, first NOR gate 402A comprises an output terminal coupled to a first input terminal of eleventh NOR gate 410. Second NOR gate 402B comprises an output terminal coupled to a second input terminal of eleventh NOR gate 410 and third NOR gate 402C comprises an output terminal coupled to a third input terminal of eleventh NOR gate 410. The eleventh NOR gate 410 comprises an output terminal coupled to a first input terminal of a fourteenth NOR gate 416, the twelfth NOR gate 412 comprises an output terminal coupled to a second input terminal of the fourteenth NOR gate 416 and the thirteenth NOR gate 414 comprises an output terminal coupled to a third input terminal of the fourteenth NOR gate 416. The tenth NOR gate 408 in not connected to an input terminal of the fourteenth NOR gate 416 and instead bypasses the fourteenth NOR gate 416 having an output terminal connected to a first input terminal of a fifteenth NOR gate 418. The fifteenth NOR gate 418 comprises a second input terminal coupled to an output terminal of the fourteenth NOR gate 416. The fifteenth NOR gate 418 comprises an output terminal coupled to an input terminal of a first NOT gate 420. The first NOT gate 420 comprises an output terminal configured to output an OR write word line OR_WWL rise or fall signal corresponding to an inverted clock B rise or fall signal NCLK signal.

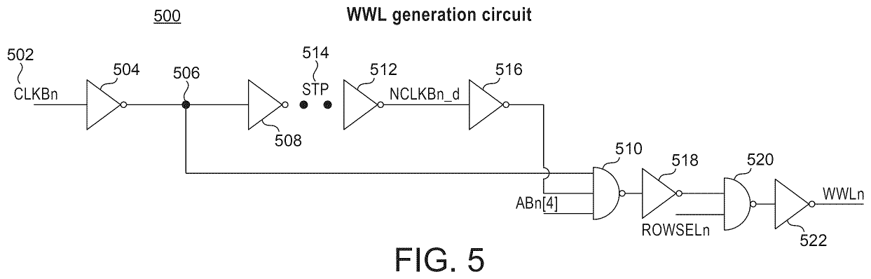

FIG. 5 shows a circuit 500 for write word line signal generation. Clock B (CLKBn) 502 representing a write clock is coupled to an input terminal of a first NOT gate 504 comprising an output terminal coupled to a first node 506. The first node 506 is coupled in a first signal flow path to an input terminal of a second NOT gate 508 and in a second signal flow path coupled to a first input terminal of a first NAND gate 510. The first signal flow path from the first node 506 to the input terminal of the second NOT gate 508 continues to a third NOT gate 512 by way of a self-timed path 514 (STP), which in operation causes a self-timed path delay.

The self-timed path 514 is a mechanism that controls a falling time of the write word line determined by self-timed path delay. The self-timed path delay is operable for the duration of an activation signal for the write word line during a write operation. The self-timed path delay causes the write word line to be activated for an appropriate amount of time to reliably write data to a memory cell without causing unwanted power consumption. In operation, when a write operation is triggered, a write enable signal activates the write word line by way of the self-timed path delay. The self-timed path 514 when fabricated includes delay elements that determine the duration of the self-timed path delay once the write word line is triggered. Once the duration of delay has finished, then the write word line is deactivated, thus completing the write operation.

Accordingly, the self-timed path 514 provides a timing control based on the characteristics of the memory cells and overall design of the memory system. Any delay in the first signal flow path ensures that the write word line is activated for a precise duration. The delay can be implemented by metal traces, RC (resistor capacitor) delay, digital counters or clocked delay lines. An output terminal of the third NOT gate 512 is coupled to an input terminal of a fourth NOT gate 516 which comprises an output terminal coupled to a second input terminal of the first NAND gate 510. The first NAND gate comprises a third input terminal to receive an ABn signal, a line activation signal. In operation, a write word line comes at a trigger of falling edge of clock B. As Clock B comes it is inverted to trigger a NAND gate. Any input on NAND will trigger it to be a 1 so wait for signal on the NAND.

An output terminal of the first NAND gate 510 is coupled to an input terminal of a sixth NOT gate 518. An output terminal of the sixth NOT gate 518 is coupled to a first input terminal of a second NAND gate 520. The second NAND gate 520 comprises a second input terminal to receive a row select signal ROWSELn used to select a specific row in the memory circuit. An output terminal of the second NAND gate 520 is coupled to an input terminal of the seventh NOT gate 522 which comprises an output terminal configured to output the write word line signal.

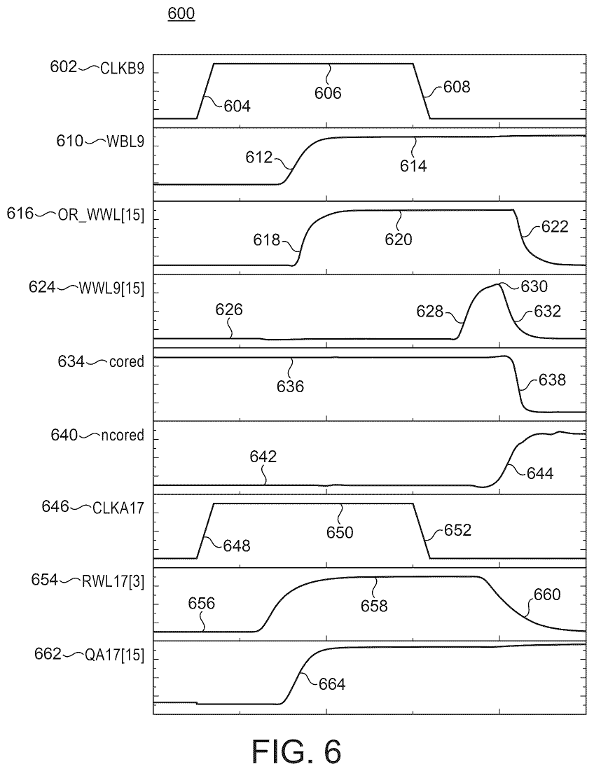

FIG. 6 shows a series of signal waveforms 600 generated from the logic circuits of FIGS. 2 to 6.

The signal waveforms comprise Clock B signal waveform 602 representing a write clock and having a rising edge 604, a plateau 606 where the signal maintains a substantially specific constant value over time and a falling edge 608.

A write bit line WBL signal waveform 610 comprises a rise 612 followed by a plateau 614 where the signal maintains a substantially specific constant value over time. In the present example a 1 (high) state is being written. The WBL signal can of course go either way from low to high 0 to 1 or high to low 1 to 0.

An OR write word line signal OR_WWL waveform 616 comprises an OR version of the write word line WWL and comprises a rise 618, followed by a plateau 620 where the signal maintains a substantially specific constant value over time, followed by a fall 622.

The write word line WWL signal waveform 624 comprises an extended plateau low stage 626 where the signal maintains a substantially specific constant value over time continuing to a rise 628 before peaking 630 and then entering a fall stage 632.

A cored signal waveform 634 used to control or select a specific core, row or section of a memory array comprises a high plateau 636 where the signal maintains a substantially specific constant value over time before entering a fall 638. A ncored signal waveform 640 is a complementary or opposite control signal to the cored signal waveform 634. Ncored signal 640 may be used to deselect a core, row or section of the memory array. Nocored signal 640 comprises a low plateau 642 where the signal maintains a substantially specific constant value over time before entering a rise 644.

The signal waveforms comprise Clock A signal waveform 646 representing a read clock and having a rising edge 648, a plateau 650 where the signal maintains a substantially specific constant value over time and a falling edge 652.

The signal waveforms comprise a read word line signal waveform 654 comprising a plateau 656 where the signal maintains a substantially specific constant value over time, a rising edge 658 and a falling edge 660.

A QA signal waveform 662 refers to the output signal of a particular storage node (flip-flop or latch). The QA signal waveform comprises a rise 664 representing a 1 or high state, but could of course go either way from low to high 0 to 1 or high to low 1 to 0.

Referring to FIG. 6, present techniques of clocking scheme embodied by the signal waveforms 602 to 662 described herein provide reduced or no active bit line to write line coupling. For example:
WBL is triggered by CLKB rising edge;
WWL is triggered by CLKB falling edge;
WBL and WWL are in separate clock phases to resolve or at least mitigate WBL to WWL dynamic coupling issues.

In order to resolve unknown output “x” during address collision, present techniques of clocking scheme embodied by the signal waveforms 602 to 662 described herein provide:
RWL is triggered by CLKA rising edge;
WWL is triggered by CLKB rising edge;
The bitcell content is known in the CLK high phase and is therefore not an unknown “x”. Because the RWL and WWL signals are in separate clock phases, the collision issue is resolved.

Additionally, OR_WWL is triggered by a CLKB rise as compared to a CLKB fall in many sate of the art multi-port memory system designs. The OR_WWL signal comes relatively early and sets up a bitcell latch for write. This technique improves write time as a bitcell flip is waiting on WWL assertion and improves internal margins between OR_WWL and WWL signals.

As can be seen from FIG. 6, WWL rise is triggered by CLKB fall in a second phase of the clock and as seen in circuit 500 of FIG. 5, a self-timed path delay determines the WWL fall. WBL is triggered by CLKB rise in a first phase of CLKB rise and also the OR_WWL rise is triggered by the CLKB rise in the first phase.

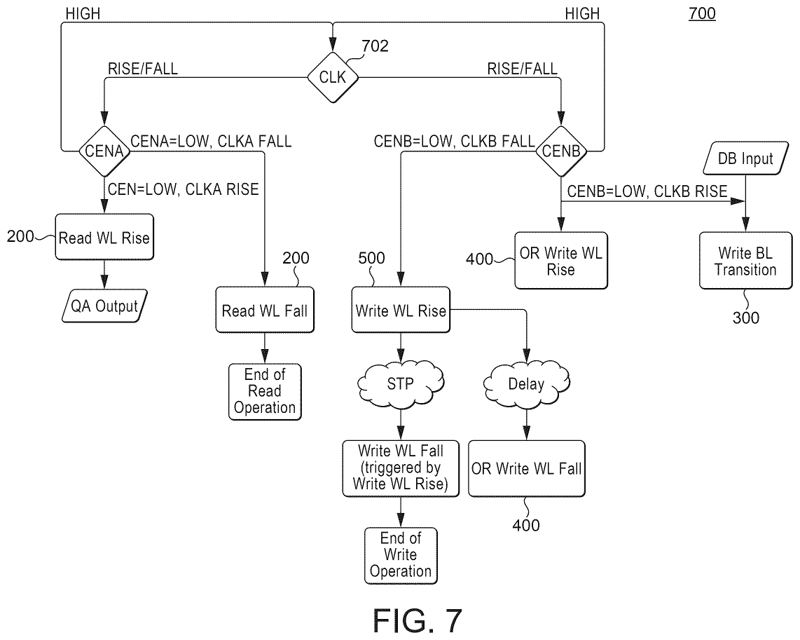

FIG. 7 shows a signal flow chart for a read and write operation 700 in a multi-port register circuit according to present techniques. To summarise the flow of FIG. 7, the flow can be split into a read and a write operation.

### Read Operation

Clock 702 operates to control a clock A (CKLA) in a read domain illustrated as a rise or fall of CLKA in FIG. 7.
CLKA rise triggers Read WL (RWL) signal.
Memory contents are read out on QA pin. (CLKA phase 1)
CLKA fall triggers RWL fall.

### Write Operation

Clock 702 operates to control a clock B (CKLB) in a write domain illustrated as a rise or fall of CLKB in FIG. 7.
CLKB rise triggers the Write BL (WBL) signal transition
Sets up the data to bitcell latch based on DB input.
CLKB rise also triggers a signal which is OR function of all Write Write WL (OR_WWL)
OR_WWL comes early and sets up the bitcell latch for write.
CLKB fall triggers the Write WL (WWL) signal assertion
Completes the write operation in the bitcell (CLKB phase 2)
Self-timed Path (STP) delay determines WWL fall

In further detail, the signal flow chart for a read and write operation 700 shows how the different read and write blocks in the memory are triggered and asserted and de-asserted. The logic circuits shown in FIGS. 2 to 6 enable the signal flow. Clock 702 is coupled to both clock A and clock B in the system design in the memory where clock A rises to trigger the read word line rise and as soon as the read word line rise happens, the memory bitcell contents are then transferred to the Q pin and then the clock A fall triggers the read word line fall.

Circuit 200 as shown in FIG. 2 is configured to generate read word line generation. Circuit 200 controls both a read WL rise and a read WL fall depending upon whether a rising or falling clock signal is applied. CEN is the chip enable for read port and the CEN is not enabled when read operations are not selected.

In a write operation, the clock B rise triggers the write bit line rise or fall depending on writing a 0 or a 1 to trigger a transition to set up data that is being written to a bitcell latch. Write bit lines contain the data to set a 0 or 1. As soon as the write clock comes the write bit lines come too and get triggered.

Circuit 400 as shown in FIG. 4 controls both an OR Write WL Rise and an OR Write WL Fall depending upon whether a rising or falling clock signal is applied. Therefore, 400 comprises a CLKB clock B rise that also triggers a signal which is a OR function of all Write WL (OR_WWL).

As an example, in a case of writing to any of, for example, 10 write ports, the OR WWL is the OR version of the WWL and the circuit is Circuit 400 as shown in FIG. 4 and is or′ing all the clocks. The OR word line's job is that whenever a clock B rise comes it prepares the bitcell latch to be written. In operation this opens the latch of FIG. 1 104 and prepares the write bit lines and the OR lines. In embodiments, the latch 104 is ready to be written but the state signal has not been sent as yet.

In state of the art memory cells it is typical that in a memory the clock B rise would also trigger the write word line, but in present techniques we are using the clock B falling edge to trigger the write word line and that changes the phase in which the write word line is toggled so looking at the signal figures, one can appreciate that the clock B rise triggers the write bit line and also triggers the OR write word line, but did not trigger the write word line so the actual write operation happens here at the fall of the clock B.

In operation a write bit line WBL comes at this point to write a O or 1 and OR WWL comes in to prepare the latch 104 to take whatever is on the write ports onto the storage node. So, waiting for activation of the write word line and only when write word line comes does the NMOS transistor become a pass then the process enables a write pass to the write bit line to bitcell storage node.

Since the write word line comes in the second phase of the clock now the write bit line and write word line are in separate phases. Present techniques seek to mitigate one of the issues being coupling where typically the write word line also comes early at the same time and the write bit line can go either way from 0 to 1 or 1 to 0 and the could couple back to write word line. Any dependency is removed.

Also the read word line and write word line are in separate phases so that seeks to mitigate the collision issue because now whenever the clock comes and both clock A and clock B get triggered, we know that the write will only occur in the next phase so when the read word lines comes we can determine realistically what that bitcell content state is because we are not going to write it just yet and instead wait for the falling edge of Clock B.

As shown in FIG. 7, a self-timed path delay is involved in the write word falling. Optionally a self-timed path can be a component triggering an inverter ahead of logic circuitry with any self-timed delay depending on the amount of logic. A falling edge as a self-timed part should be enough for the duration of the write word line and enough pulse for the write bit line to get on the storage node and flip the bitcell. A self-timed path may have a number of stages and sometimes includes some metal RC tracking delay and some dummy loads. The write word line fall is therefore a self-triggered part.

Write word line rise triggers the writing of the bitcell part where you are transferring the data from the write bit line to the storage node. The fall basically signals the end of the operation.

In some techniques, each transistor in the multiple sets of transistors is implemented with an n-type transistor designated by a “N”, e.g. N15. In some techniques, each transistor in the multiple sets of transistors is implemented with a p-type transistor designated by a “P”, e.g. P4. However, other implementations and configurations can be used to achieve similar results such that each transistor can be implemented with p-type transistors or an n-type transistor.

The examples and conditional language recited herein are intended to aid the reader in understanding the principles of the present technology and not to limit its scope to such specifically recited examples and conditions. It will be appreciated that those skilled in the art may devise various arrangements which, although not explicitly described or shown herein, nonetheless embody the principles of the present technology and are included within its scope as defined by the appended claims.

Furthermore, as an aid to understanding, the above description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to limit the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes which may be substantially represented in computer-readable media and so executed by a computer or processor, whether or not such computer or processor is explicitly shown.

It will be clear to one skilled in the art that many improvements and modifications can be made to the foregoing exemplary embodiments without departing from the scope of the present techniques.

What is claimed is:

1. A clocking scheme for a driving a first signal and a write word line signal to a multi-port memory device, the clocking scheme comprising:
a clock configured to control timing of operations within the multi-port memory device, wherein the clocking scheme includes at least two separate clocking phases; and
activating the first signal line and the write word line in different clock phases of the clocking scheme, such that the first signal line is activated in a first clock phase and the write word line is activated in a second clock phase.

2. The clocking scheme of claim 1, wherein the clocking scheme comprising a clock signal having a rising edge in the first clock phase and a falling edge in the second clock phase.

3. The clocking scheme of claim 1, wherein the first signal line is a write bit line.

4. The clocking scheme of claim 3, wherein the write bit line is triggered to rise at the rising edge of the clock signal and the write word line is triggered to rise at the falling edge of the clock signal.

5. The clocking scheme of claim 4, wherein the write word line rise triggers a writing of data from the write bit line to a storage node of a bit cell.

6. The clocking scheme of claim 5, wherein the writing of data is a state of a 0 or 1.

7. The clocking scheme of claim 4, wherein a falling time of the write word line is determined by self-timed path delay.

8. The clocking scheme of claim 1, wherein the first signal line is an OR write word line.

9. The clocking scheme of claim 8, wherein the OR write word line is triggered to rise at the rising edge of the clock signal and the write word line is triggered to rise at the falling edge of the clock signal.

10. The clocking scheme of claim 1, wherein the first signal line is a read word line.

11. The clocking scheme of claim 10, wherein the read word line is triggered to rise at the rising edge of the clock signal and the write word line is triggered to rise at the falling edge of the clock signal.

12. The clocking scheme of claim 1, wherein the clocking scheme comprises a clock coupled to a both a read clock and a write clock.

13. The clocking scheme of claim 12, wherein for a read operation the read clock rises to trigger a read word line rise followed by the read clock falling to trigger the read word line fall.

14. The clocking scheme of claim 12, wherein for a write operation the write clock rises to trigger a write bit line rise or fall.

15. The clocking scheme of claim 14, wherein for a write operation the write clock falls to trigger write word line rise at the falling edge of the write clock.

16. A logic circuit for driving signals to a multi-port memory device, the logic circuit comprising:
a first signal line;
a write word line;
a clocking scheme configured to control timing of operations within the multi-port memory device, wherein the clocking scheme includes at least two separate clocking phases;
wherein the first signal line and the write word line are activated in different clock phases of the clocking scheme, such that the first signal line is activated in a first clock phase and the write word line is activated in a second clock phase.

17. The logic circuit as claimed in claim 16, wherein the first signal line is a write word line configured as an OR of the write word lines of all different write ports.

18. The logic circuit as claimed in claim 17, wherein the OR of the write word line is generated by an input array of write ports each coupled to an input of a first NOR gate, wherein at least three first NOR gates are coupled to an input of a second NOR gate coupled to an input of a NAND gate and wherein the NAND gate is coupled to an input of a third NOR gate connected to an input of a NOT gate.

19. The logic circuit as claimed in claim 18, wherein the input of the NAND gate is coupled to at least three second NOR gates and wherein the third NOR gate is coupled at an input to an output of a first NOR gate and an output of the NAND gate.

20. A non-transitory computer-readable medium to store computer-readable code for fabrication of the circuit of claim 16.
